(19) United States
(12) Patent Application Publication
(10) Pub. No.: US 2010/0170568 A1
(43) Pub. Date: Jul. 8, 2010

(54) AG ELECTRODE PASTE, SOLAR BATTERY CELL, AND METHOD OF MANUFACTURING THE SAME

(75) Inventor: Yoshihiro KAWAGUCHI, Kyoto-shi (JP)

Correspondence Address: DICKSTEIN SHAPIRO LLP, 1633 Broadway, NEW YORK, NY, 10019, US

(73) Assignee: MURATA MANUFACTURING CO., LTD, Nagaokakyo-shi (JP)

(21) Appl. No.: 12/730,392

(22) Filed: Mar. 24, 2010

Related U.S. Application Data
(63) Continuation of application No. PCT/JP2008/064705, filed on Aug. 18, 2008.

(30) Foreign Application Priority Data
Sep. 27, 2007 (JP) 2007-251609

(51) Int. Cl. H01L 31/0224; H01L 21/28; H01B 1/22

(52) U.S. Cl. 136/256; 438/660; 252/519.3; 257/E31.124; 257/E21.158

(57) ABSTRACT

Ag electrode paste for forming a light-reception-surface-side electrode, with which a solar battery cell having a light-reception-surface-side electrode low in line resistance and achieving high conversion efficiency can be obtained, a solar battery cell having good characteristics manufactured therewith, and a method of manufacturing the same are provided. A silver electrode paste contains (a) Ag particles, (b) an organic vehicle, and (c) lead-free glass fit containing 13 to 17 weight % SiO₂, 0 to 6 weight % B₂O₃, 65 to 75 weight % Bi₂O₃, 5 weight % Al₂O₃, 1 to 3 weight % TiO₂, and 0.5 to 2 weight % CuO is employed as a Ag electrode paste used for forming a light-reception-surface-side electrode. A Ag electrode paste is used for forming a second electrode of the light-reception-surface-side electrode which includes a first electrode and the second electrode disposed on the first electrode.

This is a continuation of application Serial No. PCT/JP2008/064705, filed Aug. 18, 2008, the contents of which are incorporated herein by reference.

### TECHNICAL FIELD

The invention of the present application relates to Ag electrode paste, a solar battery cell having a light-reception-surface-side electrode formed with the same, and a method of manufacturing a solar battery cell including the step of forming a light-reception-surface-side electrode with the Ag electrode paste.

### BACKGROUND ART

A method of manufacturing a solar battery cell, in which a PN junction is formed on a semiconductor substrate, thereafter a comb-shaped finger electrode and a bus bar electrode connected to the finger electrode are formed on at least one main surface of the semiconductor substrate, and the bus bar electrode having a two-layered structure is formed by printing conductive paste twice followed by firing, is disclosed as a conventional method of manufacturing a solar battery cell (see FIGS. 1 to 4 of Patent Document 1).

According to this method of manufacturing a solar battery cell, the conversion efficiency of a solar battery cell is improved by ensuring ohmic contact between an Ag electrode and an Si substrate through the bus bar electrode in the first layer out of the bus bar electrodes (in the example, the Ag electrode) stacked in two layers on a surface of the solar battery cell and by lowering the electrode line resistance in the bus bar electrode in the second layer.

In addition, proposed for use in a Ag/Al electrode paste for a crystalline silicon solar battery cell is a lead-free glass fit composed of (Patent Document 2):

0.5 to 35 wt % SiO₂;

0 to 5 wt % Al₂O₃;

1 to 15 wt % B₂O₃:

0 to 15 wt % ZnO; and

55 to 90 wt % Bi₂O₃.

In the case of a solar battery cell having a two-layered bus bar electrode (a light-reception-surface-side electrode) implemented by Ag electrodes as in Patent Document 1 above, the glass fit contained in the Ag electrode paste for forming the bus bar electrode in the upper layer flows to the surface of the bus bar electrode on the upper layer side during firing of the electrode, which may lead to lower solderability, for example, in soldering a lead or the like to the upper layer side.

If the glass frit contained in the Ag electrode paste for forming the bus bar electrode on the upper layer side excessively flows on the lower layer side of the bus bar electrode, the ohmic contact between the bus bar electrode lower layer side and the Si substrate is impeded and the conversion efficiency of the solar battery cell may be lowered.

Further, if sintering of the bus bar electrode upper layer side is completed before gas generated from the bus bar electrode (the Ag electrode) lower layer side (i.e., a decomposition gas, a combustion gas or the like of a binder) during firing of the Ag electrode paste completely escapes, the gas disadvantageously causes blister.

The electrode paste in Patent Document 2 is for a Ag/Al electrode, and this document does not provide information useful for lead-free glass fits used for the Ag electrode paste to be used in the present application. Namely, this document does not suggest a method of obtaining a solar battery cell having better characteristics in forming an Ag electrode as a light-reception-surface-side electrode of the solar battery cell.

### Patent Document 1: Japanese Patent Laying-Open No. 2006-339342

### Patent Document 2: Japanese Patent Laying-Open No. 2006-313744

### DISCLOSURE OF THE INVENTION

### Problems to be Solved by the Invention

The present invention was made in view of the circumstances above, and an object thereof is to provide Ag electrode paste for forming a light-reception-surface-side electrode, with which a solar battery cell having a light-reception-surface-side electrode which is low in line resistance and achieving high conversion efficiency can be obtained, a solar battery cell having good characteristics manufactured therewith, and a method of manufacturing the same, and further to provide a Ag electrode paste with which the line resistance of the light-reception-surface-side electrode can be lowered even though the light-reception-surface-side electrode has a two-layered structure and a solar battery cell achieving high conversion efficiency can be obtained without increasing the interface resistance between the Ag electrode (first electrode) on a lower layer side and a semiconductor substrate, a solar battery cell having good characteristics manufactured therewith, and a method of manufacturing the same.

### Means for Solving the Problems

In order to solve the problem above, a Ag electrode paste according to the present invention is used to form a light-reception-surface-side electrode of a solar battery cell including a semiconductor substrate, the light-reception-surface-side electrode arranged on a main surface functioning as a light reception surface on a pair of main surfaces of the semiconductor substrate opposed to each other, and a back electrode arranged on the other main surface, and the Ag electrode paste contains:

(a) Ag particles;

(b) an organic vehicle; and

(c) a lead-free glass frit containing 13 to 17 weight % SiO₂, 0 to 6 weight % B₂O₃, 65 to 75 weight % Bi₂O₃, 1 to 5 weight % Al₂O₃, 1 to 3 weight % TiO₂, and 0.5 to 2 weight % CuO.

In addition, when the light-reception-surface-side electrode includes a first electrode obtained by firing a first Ag electrode paste and a second electrode obtained by firing a second Ag electrode paste disposed on the first electrode, a particular Ag electrode paste is used as the second Ag electrode paste.

Alternatively, a solar battery cell according to the present invention is a solar battery cell including a semiconductor substrate, a light-reception-surface-side electrode arranged on one main surface of a pair of main surfaces of the semiconductor substrate opposed to each other, and a back electrode arranged on the other main surface, the light-reception-surface-side electrode including a first electrode obtained by a firing first Ag electrode paste and a second electrode obtained by firing a second Ag electrode paste formed on the first electrode, and the Ag electrode paste of the invention being used as the second Ag electrode paste.

In addition, a method of manufacturing a solar battery cell including a semiconductor substrate, a light-reception-surface-side electrode arranged on one main surface functioning as the light reception surface of a pair of main surfaces of the semiconductor substrate opposed to each other, and a back electrode arranged on the other main surface and having such a structure that the light-reception-surface-side electrode includes a first electrode obtained by firing a first Ag electrode paste and a second electrode obtained by firing a second Ag electrode paste formed on the first electrode, and the method includes the steps of: forming an Ag electrode paste pattern for the first electrode by applying the first Ag electrode paste in a prescribed pattern onto the semiconductor substrate; forming an Ag electrode paste pattern for the second electrode by applying the Ag electrode paste of the invention in a prescribed pattern onto the Ag electrode paste pattern for the first electrode; and simultaneously firing the Ag electrode paste pattern for the first electrode and the Ag electrode paste pattern for the second electrode.

### EFFECTS OF THE INVENTION

The Ag electrode paste according to of the present application can be used for forming a light-reception-surface-side electrode of a solar battery cell, contains Ag particles, an organic vehicle, and a lead-free glass frit. The lead-free glass frit contains 13 to 17 weight % SiO₂, 0 to 6 weight % B₂O₃, 65 to 75 weight % Bi₂O₃, 1 to 5 weight % Al₂O₃, 1 to 3 weight % TiO₂, and 0.5 to 2 weight % CuO.

As the lead-free glass frits contains a proper amount of CuO, the start of sintering of the electrode is delayed. In addition, as the lead-free glass frit contains a proper amount of Al₂O₃ and TiO₂ in the glass, crystallization is less likely and moderate flowability is ensured so that the glass moderately flows to the interface of the semiconductor substrate in the firing step. The glass can therefore be prevented from sintering in such a state that the glass floats and remains at the surface of the Ag electrode and good solderability can be ensured. Moreover, the Ag electrode paste according to the present invention containing the lead-free glass frit achieves a low resistance sintered object formed after firing, and it can form an electrode low in line resistance as the light-reception-surface-side electrode of the solar battery cell. Further, the sintering is not completed before a binder decomposition gas or the like completely escapes, so that occurrence of blister can be prevented.

In addition, in an example where the light-reception-surface-side electrode includes the first electrode obtained by firing the first Ag electrode paste and the second electrode obtained by firing a second Ag electrode paste formed on the first electrode, when a Ag electrode paste according to the present invention is used as the second Ag electrode paste, the lead-free glass frit used for the Ag electrode paste according to the present invention do not impede the ohmic contact between the first electrode, which is the electrode in the first layer, and the semiconductor substrate even though it flows into the first electrode in the firing step. Good ohmic contact can thus be ensured between the first electrode and the semiconductor substrate, and a solar battery cell achieving high conversion efficiency can be obtained.

Therefore, by using the Ag electrode paste according to the present invention as the Ag electrode paste for forming the second electrode, the line resistance of the electrode can be lowered and the interface resistance between the first electrode (the electrode in the first layer) and the semiconductor substrate is not increased. A solar battery cell achieving high conversion efficiency can thus be obtained. Further, the occurrence of defects such as blisters, caused by sintering of the second electrode before complete escape of a decomposition gas, a combustion gas or the like of the binder for the first electrode can be prevented.

Alternatively, in an example where the light-reception-surface-side electrode includes the first electrode obtained by firing the first Ag electrode paste and the second electrode obtained by firing the second Ag electrode paste formed on the first electrode, the Ag electrode paste described above is used as the second Ag electrode paste in a solar battery cell according to the present invention. A highly reliable solar battery cell having low line resistance electrode and low interface resistance between the first electrode (the electrode in the first layer) and the semiconductor substrate, achieving high conversion efficiency, and free from defects such as blisters can thus be provided.

Further, in a method of manufacturing a solar battery cell according to the present invention, the Ag electrode paste pattern for the first electrode is formed by applying the first Ag electrode paste in a prescribed pattern onto the semiconductor substrate, the Ag electrode paste pattern for the second electrode is formed by applying the Ag electrode paste of the invention in a prescribed pattern onto the Ag electrode paste pattern for the first electrode, and thereafter the Ag electrode paste pattern for the first electrode and the Ag electrode paste pattern for the second electrode are simultaneously fired. A highly reliable solar battery cell having a low line resistance electrode and a low interface resistance between the first electrode and the semiconductor substrate, achieving high conversion efficiency, and free from defects such as blisters can thus efficiently be manufactured.

### BRIEF DESCRIPTION OF THE DRAWINGS

FIG. 1 is a plan view of a solar battery cell having a light-reception-surface-side electrode formed with Ag electrode paste according to the present invention.

FIG. 2 is an enlarged view of a cross-section of the solar battery cell in FIG. 1.

FIG. 3 is a diagram showing a structure of a semiconductor substrate for evaluating a contact resistance, fabricated in an example of the present invention.

### DESCRIPTION OF THE REFERENCE SIGNS

1 semiconductor substrate
2 n-type impurity layer
3 anti-reflection coating
10 light-reception-surface-side electrode
11 first electrode
12 second electrode
20 back electrode
L distance between electrodes
Z length of electrode

### BEST MODES FOR CARRYING OUT THE INVENTION

A Ag electrode paste according to the present invention is prepared by blending Ag particles, lead-free glass frit, and an organic vehicle.

The Ag particles (Ag powders) used in the Ag electrode paste according to the present invention are not particularly restricted, and Ag particles having various properties such as scale-like powders, spherical powders, powders in irregular shape, or mixture thereof, may be employed.

The Ag particle has an average particle size (D50) which is preferably not greater than 20 μm, and more preferably in a range from 0.1 to 10 μm.

When the Ag particle has an average particle size exceeding 20 μm, the printability of the Ag electrode paste becomes poor, which is not preferred.

It is noted that various Ag particles, for example, Ag particles having various properties such as scale-like powders, spherical powders or powders in irregular shape, or a mixture of Ag particles different in particle size within the range above, may be employed, alone or in combination of two or more of them.

The ratio amount of blended Ag particles is preferably in a range from 70 to 92 weight % with respect to the entire Ag electrode paste before firing. When the amount of Ag particles is lower than 70 weight %, the conductive component is excessively low and the firing density of the electrode is lowered. When the amount of Ag particles exceeds 92 weight %, the viscosity is significantly high and printability or ease of application becomes poor.

The organic vehicle (for example, a vehicle obtained by dissolving a binder resin in a solvent) used for the Ag electrode paste according to the present invention is not particularly restricted, and various thermally decomposable materials which have conventionally been used as a firing-type resin composition can be employed. Examples thereof include cellulosic derivatives such as methylcellulose, ethyl cellulose and carboxymethyl cellulose, polyvinyl alcohols, polyvinyl pyrrolidones, acrylic resins, vinyl acetate-acrylic ester copolymers, butyral resin derivatives such as polyvinyl butyral, alkyd resins such as phenol-modified alkyd resin and castor oil fatty acid modified alkyd resin. These resins can be used alone or in combination of two or more types.

Various solvents capable of dissolving the binder resin above can be used as the solvent for the organic vehicle (the binder resin) above. In the Ag electrode paste according to the present invention, an organic vehicle obtained by dissolving the binder resin in a solvent in advance is preferably used in a manner mixed with Ag particles and lead-free glass frits.

Examples of the solvent include dioxane, hexane, toluene, ethyl cellosolve, cyclohexanone, butyl cellosolve, butyl cellosolve acetate, butyl carbitol acetate, diethylene glycol diethyl ether, diacetone alcohol, terpineol, and benzyl alcohol.

In the Ag electrode paste according to the present invention, 13 to 17 weight % SiO₂ powder, 0 to 6 weight % B₂O₃ powder, 65 to 75 weight % Bi₂O₃ powder, 1 to 5 weight % Al₂O₃ powder, 1 to 3 weight % TiO₂ powder, and 0.5 to 2 weight % CuO powder are blended for use as the lead-free glass frit.

In the present invention, the shape of the lead-free glass frits are not particularly limited, and fits having various properties such as spherical shape or crushed powder shape can be employed.

It is noted that the lead-free glass frit preferably has an average particle size (D50) in a range from 0.1 to 5 μm.

In addition, the amount of blended lead-free glass frits is preferably in a range from 0.1 to 10 parts by weight with respect to 100 parts by weight of the Ag particles, which are conductive powders. Further, from a point of view of avoiding peel-off of an electrode obtained by firing the Ag electrode paste at the interface and floating of glass or incomplete soldering, the amount of blended lead-free glass frit is particularly preferably in a range from 1 to 5 parts by weight with respect to 100 parts by weight of the Ag particles.

Each component in the lead-free glass frit is limited as described above for the following reasons. The amount of SiO₂ is set in a range from 13 to 17 weight %. When the amount of SiO₂ is lower than 13 weight %, the chemical durability of glass is lowered and the moisture resistance as the Ag electrode also deteriorates. When the amount of SiO₂ exceeds 17 weight %, the softening point of glass becomes excessively high, glass is likely to float at the surface of the Ag electrode, and solderability significantly deteriorates.

The amount of B₂O₃ is set in a range from 0 to 6 weight %. When the amount of B₂O₃ exceeds 6 weight %, the softening point of glass is lowered and wettability of the glass to Ag becomes excessively high, and the glass tends to flow into the first electrode which is the electrode in the first layer and electrical contact between the first electrode and the semiconductor substrate is impeded.

When B₂O₃ is present, the stability as glass is improved. However, B₂O₃ is not necessarily in the Ag electrode paste according to the present invention.

The amount of Bi₂O₃ is set in a range from 65 to 75 weight %. When the amount of Bi₂O₃ is lower than 65 weight %, the softening point of glass becomes higher, the glass tends to remain at the surface of the Ag electrode in a floating state, and solderability significantly deteriorates. When the amount of Bi₂O₃ exceeds 75 weight %, the softening point of the glass is lowered, the amount of flow to the interface between the first electrode in the first layer and the semiconductor substrate increases, and electrical contact between the Ag electrode and the semiconductor substrate is impeded.

The amount of Al₂O₃ is set in a range from 1 to 5 weight %. When the amount of Al₂O₃ is lower than 1 weight %, crystallization of glass is likely, which results in glass without flowability, and solderability of the second electrode in the second layer is lowered. When the amount of Al₂O₃ exceeds 5 weight %, the softening point temperature of the glass is raised, and in this case as well, solderability of the second electrode in the upper layer side is lowered.

The amount of TiO₂ is set in a range from 1 to 3 weight %. When the amount of TiO₂ is lower than 1 weight %, stability of glass becomes poor. When the amount of TiO₂ exceeds 3 weight %, crystallization of the glass is likely and flowability and stability of the glass are lowered. By setting the ratio of TiO₂ to 1 to 3 weight %, flowability of the glass and stability of the glass in a high temperature range can be ensured.

CuO has a function to enhance absorption of heat by glass itself and to achieve efficient heating in a near-infrared furnace. When heat absorption by the glass itself is high, glass fits in irregular shape become spherical and wettability to Ag powders becomes poor. Therefore, the temperature at which sintering of the Ag electrode starts can be moved to a high temperature side. Consequently, occurrence of blisters or the like caused by completion of sintering of the second electrode in the second layer before a decomposition gas or the like of a binder generated from the first electrode in the first layer completely escapes can be prevented.

The amount of CuO is set in a range from 0.5 to 2 weight %. When the amount of CuO is lower than 0.5 weight %, the heat absorption efficiency of glass itself does not become too high. When the amount of CuO exceeds 2 weight %, crystallization of the glass is likely, flowability of the glass is lowered, and solderability tends to deteriorate.

The Ag electrode paste according to the present invention can be manufactured, for example, by mixing the Ag particles, the organic vehicle and the lead-free glass frits described above and thereafter further performing a kneading and mixing process using a triple roll mill followed by pressure reduction and degassing.

Solar Battery Cell According to the Present Invention

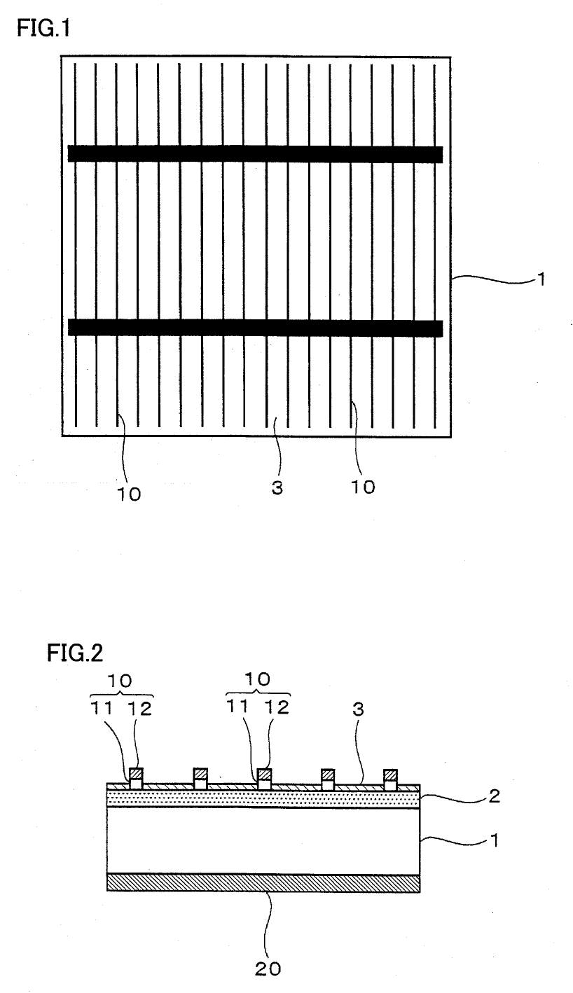

FIG. 1 is a plan view of a solar battery cell having a light-reception-surface-side electrode formed with the Ag electrode paste according to the present invention, and FIG. 2 is an enlarged view of a cross-section.

In this solar battery cell, a substrate (an Si semiconductor substrate) having an n-type impurity layer 2 to a depth of approximately 0.3 to 0.5 μm formed by diffusion of phosphorus on one main surface side of a p-type Si semiconductor substrate having a thickness of approximately 500 μm, is used as a semiconductor substrate 1.

In addition, an anti-reflection coating 3 is formed on one surface of semiconductor substrate 1 (the surface where n-type impurity layer 2 is formed) to function as a light reception surface. It is noted that a film made of a material such as SiNx, SiO₂, TiO₂, or the like, is normally used as anti-reflection coating 3.

On the surface of semiconductor substrate 1 where the anti-reflection coating 3 is formed (one main surface), a light-reception-surface-side electrode 10 for extracting a negative (minus) potential from n-type impurity layer 2 is formed.

Light-reception-surface-side electrode 10 includes a first electrode 11 which is on the lower layer side and formed by applying and baking the Ag electrode paste, and a second electrode 12 which is on the upper layer side and formed by applying and baking a Ag electrode paste according to the present invention. First electrode 11 is formed to reach the n-type impurity layer 2 through the anti-reflection coating 3.

First electrode 11 on the lower layer side of light-reception-surface-side electrode 10 mainly aims to ensure ohmic contact with semiconductor substrate 1, that is, to ensure electrical contact between the second electrode on the upper layer side of light-reception-surface-side electrode 10 and semiconductor substrate 1.

In addition, second electrode 12 on the upper layer side of light-reception-surface-side electrode 10 mainly aims to lower the line resistance of light-reception-surface-side electrode 10.

On the surface opposed to one surface of semiconductor substrate 1 (the other main surface), a back electrode 20 for extracting a positive (plus) potential from the other main surface side of semiconductor substrate 1 is formed.

Back electrode 20 is formed by applying and baking an Al electrode paste containing Al powder as a conductive component. It is noted that an electrode composed of Al and Ag, a part of which is implemented as an Ag electrode, may also be employed as back electrode 20.

First electrode 11 of light-reception-surface-side electrode 10 is formed with a first Ag electrode paste containing Ag particles, lead-free glass frit composed as follows, and an organic vehicle.

Composition of A Lead-Free Glass Frit Contained in First Ag Electrode Paste

21.2 weight % SiO₂

54.7 weight % Bi₂O₃

18.0 weight % BaO

6.1 weight % B₂O₃

This first Ag electrode paste can also be manufactured, for example, by mixing the aforementioned Ag particles, the organic vehicle, the lead-free glass frit, and an oxide such as ZnO, TiO₂ or ZrO₂ which has the function to remove the anti-reflection coating, and thereafter further performing a kneading and mixing process using a triple roll mill followed by pressure reduction and degassing.

It is noted that paste containing 75 to 85 weight % Ag particles, 10 to 15 weight % organic vehicle, 1 to 4 weight % of the above lead-free glass frit, 2 to 6 weight % of the above oxide such as ZnO, TiO₂ or ZrO₂ may be used as the first Ag electrode paste in the present example.

Second electrode 12 of light-reception-surface-side electrode 10 is formed with a second Ag electrode paste containing the Ag particles, the lead-free glass frit and the organic vehicle, and the Ag electrode paste according to the present invention manufactured as described above is used as this second Ag electrode paste.

Light-reception-surface-side electrode 10 is formed by printing the first Ag electrode paste and the second Ag electrode paste described above in a prescribed pattern with a screen printing method and thereafter simultaneously firing the pastes in a furnace. The first and second Ag electrode pastes are directly printed on anti-reflection coating 3 and then fired. Here, first electrode 11 on the lower layer side removes anti-reflection coating 3 and contact between first electrode 11 and (n-type impurity layer 2 of) semiconductor substrate 1 is ensured.

Since light-reception-surface-side electrode 10 is soldered during assembly of a module, the second electrode 12 on the upper layer side forming light-reception-surface-side electrode 10 is required to have good solderability. In addition, since the glass contained in second electrode 12 may flow toward first electrode 11 during firing, it is necessary not to impede contact between first electrode 11 and (n-type impurity layer 2 of) the semiconductor substrate. By forming first electrode 11 and second electrode 12 with the first and second Ag electrode pastes described above, a highly reliable solar battery cell including the first and second electrodes capable of meeting the demands above can efficiently be manufactured.

As the lead-free glass frits contained in the second Ag electrode paste described above contain a proper amount of CuO, the start of sintering of the electrode is effectively delayed. In addition, since a proper amount of Al₂O₃ and TiO₂ is contained in glass, crystallization is less likely and moderate flowability is ensured. Therefore, the glass moderately flows toward the first electrode side or the interface side between the first electrode and the semiconductor substrate during firing. Consequently, the glass is less likely to float at the surface of the second electrode and good solderability can be obtained. In addition, occurrence of blisters due to sintering of the second electrode before a binder decomposition gas or the like completely escapes from the first electrode can be prevented.

In addition, the lead-free glass frit contained in the second Ag electrode paste does not impede the ohmic contact between the Ag electrode in the first layer and the semiconductor substrate even though they flow into the Ag electrode in the first layer. Therefore, the conversion efficiency of a crystalline silicon solar battery cell is not lowered, and blisters or the like do not occur either.

By using the electrode paste according to the present invention as the Ag electrode paste for the second layer, the line resistance of the electrode can be lowered and an increase in the interface resistance between the first electrode layer and the semiconductor substrate can be prevented. Consequently, a solar battery cell achieving high conversion efficiency can be obtained.

### Example 1

A non-limiting example of the invention of the present application is shown below to describe the features of the invention of the present application in further detail.

Preparation of Ag Electrode Paste

The second Ag electrode paste for forming the second electrode was prepared by blending 100 parts by weight Ag particles, 2.5 parts by weight lead-free glass fit as shown in Table 1, 20 parts by weight organic vehicle obtained by dissolving ethyl cellulose in terpineol, mixing these components, and thereafter further performing a kneading and mixing process using a triple roll mill followed by pressure reduction and degassing. It is noted that lead-free glass fits labeled as sample numbers 1 to 9 in Table 1 are lead-free glass fits satisfying the requirements of the present invention, and sample numbers 10 to 18 indicate lead-free glass fits in Comparative Examples not satisfying the requirements of the present invention.

TABLE 1

| | | | | | | | | Light-Reception-Surface-Side | | |
|---|---|---|---|---|---|---|---|---|---|---|
| | Lead-Free Glass Frit Composition | | | | | | | Electrode Characteristic | | |
| | (Weight %) | | | | | | | | Contact | |
| Sample No. | SiO₂ | B₂O₃ | Bi₂O₃ | Al₂O₃ | TiO₂ | CuO | Total | Solderability | Resistance | Blister |
| 1 (Example 1) | 15.4 | 4.9 | 73.6 | 3.2 | 2.0 | 0.9 | 100.0 | ◯ | ◯ | No |
| 2 (Example 2) | 15.5 | 4.9 | 73.9 | 3.2 | 2.0 | 0.5 | 100.0 | ◯ | ◯ | No |
| 3 (Example 3) | 15.2 | 4.8 | 72.8 | 3.2 | 2.0 | 2.0 | 100.0 | ◯ | ◯ | No |
| 4 (Example 4) | 15.6 | 5.0 | 74.4 | 3.1 | 1.0 | 0.9 | 100.0 | ◯ | ◯ | No |
| 5 (Example 5) | 15.2 | 4.9 | 72.8 | 3.2 | 3.0 | 0.9 | 100.0 | ◯ | ◯ | No |
| 6 (Example 6) | 16.0 | 5.0 | 75.0 | 1.0 | 2.0 | 1.0 | 100.0 | ◯ | ◯ | No |
| 7 (Example 7) | 15.1 | 4.8 | 72.2 | 5.0 | 2.0 | 0.9 | 100.0 | ◯ | ◯ | No |
| 8 (Example 8) | 16.0 | 5.0 | 72.6 | 3.3 | 2.1 | 1.0 | 100.0 | ◯ | ◯ | No |
| 9 (Example 9) | 15.0 | 6.0 | 72.6 | 3.3 | 2.1 | 1.0 | 100.0 | ◯ | ◯ | No |
| 10 (Comparative | 15.5 | 5.0 | 74.3 | 3.2 | 2.0 | 0.0 | 100.0 | ◯ | ◯ | Yes |
| Example 1) | | | | | | | | | | |
| 11 (Comparative | 15.1 | 4.8 | 72.0 | 3.1 | 2.0 | 3.0 | 100.0 | X | ◯ | No |
| Example 2) | | | | | | | | | | |
| 12 (Comparative | 15.7 | 5.0 | 75.0 | 3.3 | 0.0 | 0.9 | 100.0 | X | ◯ | No |
| Example 3) | | | | | | | | | | |
| 13 (Comparative | 15.1 | 4.8 | 72.0 | 3.1 | 4.0 | 1.0 | 100.0 | X | ◯ | No |
| Example 4) | | | | | | | | | | |
| 14 (Comparative | 15.9 | 5.1 | 76.0 | 0.0 | 2.1 | 0.9 | 100.0 | X | ◯ | No |
| Example 5) | | | | | | | | | | |
| 15 (Comparative | 15.0 | 4.8 | 71.4 | 6.0 | 1.9 | 0.9 | 100.0 | X | ◯ | No |
| Example 6) | | | | | | | | | | |
| 16 (Comparative | 18.2 | 5.7 | 70.0 | 3.8 | 2.3 | 1.0 | 100.0 | X | ◯ | No |
| Example 7) | | | | | | | | | | |
| 17 (Comparative | 15.0 | 7.4 | 71.0 | 3.4 | 2.2 | 1.0 | 100.0 | ◯ | X | No |
| Example 8) | | | | | | | | | | |
| 18 (Comparative | 11.7 | 3.7 | 80.0 | 2.4 | 1.5 | 0.7 | 100.0 | ◯ | X | No |
| Example 9) | | | | | | | | | | |

Ag electrode paste obtained by adding 2.5 weight % bismuth-barium-borosilicate-based glass frit, 5.0 weight % ZnO, and 20 weight % organic vehicle obtained by dissolving ethyl cellulose in terpineol, to 100 weight % Ag powder, was used as the first Ag electrode paste for forming first electrode 11 forming light-reception-surface-side electrode 10.

In this example, a solar battery cell including light-reception-surface-side electrode 10 having a two-layered structure of first electrode 11 and second electrode 12 shown in FIGS. 1 and 2 was fabricated with the first and second Ag electrode pastes prepared as described above.

A silicon substrate including an SiN_{X} film as the anti-reflection coating was employed as semiconductor substrate 1.

The light-reception-surface-side electrode 10, first electrode 11 and second electrode 12 were formed by printing the Ag electrode paste for forming the first electrode in a prescribed pattern, printing the Ag electrode paste for forming the second electrode thereon in a prescribed pattern, and thereafter simultaneously firing the pastes at 750° C., so that light-reception-surface-side electrode 10 having a two-layered structure of first electrode 11 and second electrode 12 was formed.

Solderability, the contact resistance with semiconductor substrate 1, and whether blisters occurred or not were examined for light-reception-surface-side electrode 10 of the solar battery cell fabricated as described above and the characteristics were evaluated. Table 1 shows the results together.

A solar battery cell sample labeled with each sample number in Table 1 is a sample of which the second electrode 12 of light-reception-surface-side electrode 10 was formed with the second Ag electrode paste containing a lead-free glass frits labeled with a corresponding sample number in Table 1. Solar battery cell samples labeled with sample numbers 1 to 9 are solar battery cells satisfying the requirements of the present invention, and samples labeled with sample numbers 10 to 18 are solar battery cells of the Comparative Examples not satisfying the requirements of the present invention.

In evaluating solderability, a sample labeled with each sample number was immersed in a solder bath set to 220° C. for 2 seconds, and thereafter the surface immersed in solder was visually observed. A sample having 70% or more of area wet with solder was evaluated as ∘ (pass), and a sample having less than 70% area wet was evaluated as x (fail).

In evaluating the contact resistance with semiconductor substrate 1, initially, a semiconductor substrate for evaluating a contact resistance having a light-reception-surface-side electrode formed by printing and firing Ag electrode paste for forming the first electrode and Ag electrode paste for forming the second electrode on the semiconductor substrate through steps similar to those for a sample labeled with each sample number was prepared separately from each sample.

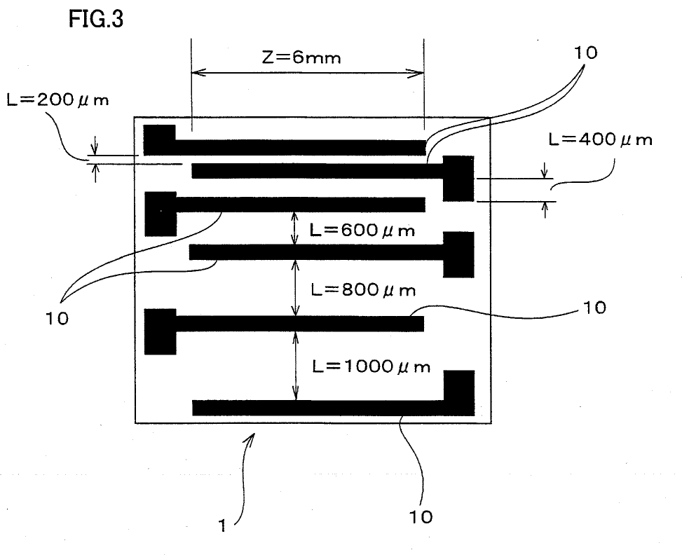

FIG. 3 is a diagram showing a structure of this sample (semiconductor substrate) for evaluating a contact resistance, and it has a structure such that a plurality of light-reception-surface-side electrodes 10 are arranged at prescribed intervals (a distance L between electrodes) as shown in FIG. 3 on the surface of substrate (semiconductor substrate) 1.

Thereafter, the contact resistance value was measured with a TLM method. Specifically, since the relationship shown in Equation (1) below holds between distance L between electrodes and measured resistance value R, the relation between distance L between electrodes and measured resistance value R was evaluated under various conditions and a contact resistance Rc was evaluated by extrapolating L to 0.

R=(L/Z)×R_{SH}+2Rc (1)

where R represents a measured resistance value, L represents a distance between electrodes, R_{SH} represents a sheet resistance of n-type Si, Z represents a length of a portion of adjacent light-reception-surface-side electrodes opposed to each other (a length of electrode), and Rc represents a contact resistance.

As a result of the evaluation above, a sample having contact resistance Rc not higher than 3Ω was evaluated as ∘ (pass), and a sample having a contact resistance exceeding 3Ω was evaluated as x (fail).

In evaluating whether blisters occurred or not, a sample labeled with each sample number was observed with an optical microscope to check whether blistering occurred at the surface of light-reception-surface-side electrode 10 or not. A sample in which blisters did not occur was evaluated as ∘ (pass), and a sample in which blisters occurred was evaluated as x (fail).

As shown in Table 1, it was confirmed that, in the case of the samples labeled with sample numbers 1 to 9 (that is, the solar battery cells in Examples 1 to 9 included in the technical scope of the present invention), the second Ag electrode paste, in which the lead-free glass frits labeled with sample numbers 1 to 9 were used, was used for forming the second electrode forming the light-reception-surface-side electrode, and solderability was good, the contact resistance was low, and occurrence of blisters was not observed.

In contrast, in the case of the sample labeled with sample number 10 (Comparative Example 1) including lead-free glass fits not containing CuO, occurrence of blisters were observed in the light-reception-surface-side electrode.

In the case of the sample labeled with sample number 11 (Comparative Example 2) including a glass frit containing 3 weight % CuO, which is out of the range of the present invention (0.5 to 2 weight %), the solderability of the light-reception-surface-side electrode was poor.

Moreover, in the case of the samples labeled with sample numbers 12 to 15 (Comparative Examples 3 to 6) including lead-free glass frits in which the Al₂O₃ and TiO₂ in the lead-free glass frits were out of the range of the present invention, crystallization of glass was likely in each case, the glass remained at the surface of the second electrode, and the solderability lowered. In the case of the sample labeled with sample number 14 (Comparative Example 5), Bi₂O₃ was also out of the range of the present invention.

In the case of the sample labeled with sample number 16 (Comparative Example 7) including a lead-free glass frit in which the content of SiO₂ was out of the range of the present invention, the softening point of glass was high, the glass remained at the surface of the second electrode, and solderability lowered.

For the sample labeled with sample number 17 (Comparative Example 8) including a lead-free glass frit in which the content of B₂O₃ was out of the range of the present invention and the sample labeled with sample number 18 (Comparative Example 9) including a lead-free glass frit in which content of Bi₂O₃ was out of the range of the present invention, the softening point of glass was low, the glass flowed to the interface between the first electrode in the first layer and the semiconductor substrate, and the contact resistance was high. In the case of the sample labeled with sample number 18 (Comparative Example 9), the SiO₂ was also out of the range of the present invention.

The results above show that a highly reliable solar battery cell including a light-reception-surface-side electrode having good solderability, achieving a low contact resistance, and free from occurrence of blisters can efficiently be manufactured with the use of the Ag electrode paste according to the invention of the present application.

The present invention is not limited to the examples above, and it is susceptible to various applications and modifications within the scope of the invention in connection with materials or configurations of a semiconductor substrate forming a solar battery cell, conditions for firing Ag electrode paste, compositions of lead-free glass frits, and the like.

### INDUSTRIAL APPLICABILITY

As described above, a highly reliable solar battery cell including a light-reception-surface-side electrode having good solderability, achieving a low contact resistance, and free from occurrence of blister can efficiently be manufactured.

Therefore, the invention of the present application is widely applicable to the technical field relating to a solar battery cell manufactured through a process of forming a light-reception-surface-side electrode with a method of applying and baking conductive paste.

1. Ag electrode paste for forming a light-reception-surface-side electrode of a solar battery cell, the solar battery cell including a semiconductor substrate, the light-reception-surface-side electrode arranged on one main surface functioning as a light reception surface being one of a pair of main surfaces of said semiconductor substrate opposed to each other, and a back electrode arranged on the other main surface, comprising:
(a) Ag particles;
(b) an organic vehicle; and
(c) lead-free glass frits containing 13 to 17 weight % SiO₂, 0 to 6 weight % B₂O₃, 65 to 75 weight % Bi₂O₃, 1 to 5 weight % Al₂O₃, 1 to 3 weight % TiO₂, and 0.5 to 2 weight % CuO.

2. The Ag electrode paste according to claim 1, wherein the Ag particles are 70 to 95 wt. % of the paste.

3. The Ag electrode paste according to claim 2, wherein the Ag particles have an average particle size not greater than 20 μm.

4. The Ag electrode paste according to claim 3, wherein the Ag particles have an average particle size of 0.1 to 10 μm.

5. The Ag electrode paste according to claim 1, wherein the glass frit is 0.1 to 10 parts per 100 parts of Ag particles.

6. The Ag electrode paste according to claim 1, wherein the glass frit is 1 to 5 parts per 100 parts of Ag particles.

7. The Ag electrode paste according to claim 6, wherein the glass frit has an average particle size of 0.1 to 5 μm.

8. The Ag electrode paste according to claim 7, wherein the Ag particles are 70 to 95 wt. % of the paste.

9. The Ag electrode paste according to claim 8, wherein the Ag particles have an average particle size not greater than 20 μm.

10. The Ag electrode paste according to claim 9, wherein the Ag particles have an average particle size of 0.1 to 10 μm, and the B₂O₃ is at least 4.8 wt % of the glass frit.

11. A solar battery cell, comprising:
a semiconductor substrate;
a light-reception-surface-side electrode arranged on one main surface of said semiconductor substrate opposed to each other; and
a back electrode arranged on the other main surface,
said light-reception-surface-side electrode comprising a first electrode which is a fired first Ag electrode paste and a second electrode which is a fired second Ag electrode paste disposed on the first electrode, and
wherein the fired second Ag electrode paste is a fired paste according to claim 10.

12. A solar battery cell, comprising:
a semiconductor substrate;
a light-reception-surface-side electrode arranged on one main surface of said semiconductor substrate opposed to each other; and
a back electrode arranged on the other main surface,
said light-reception-surface-side electrode comprising a first electrode which is a fired first Ag electrode paste and a second electrode which is a fired second Ag electrode paste disposed on the first electrode, and
wherein the fired second Ag electrode paste is a fired paste according to claim 7.

13. A solar battery cell, comprising:
a semiconductor substrate;
a light-reception-surface-side electrode arranged on one main surface of said semiconductor substrate opposed to each other; and
a back electrode arranged on the other main surface,
said light-reception-surface-side electrode comprising a first electrode which is a fired first Ag electrode paste and a second electrode which is a fired second Ag electrode paste disposed on the first electrode, and
wherein the Fired second Ag electrode paste is a fired paste according to claim 5.

14. A solar battery cell, comprising:
a semiconductor substrate;
a light-reception-surface-side electrode arranged on one main surface of said semiconductor substrate opposed to each other; and
a back electrode arranged on the other main surface,
said light-reception-surface-side electrode comprising a first electrode which is a fired first Ag electrode paste and a second electrode which is a fired second Ag electrode paste disposed on the first electrode, and
wherein the fired second Ag electrode paste is a fired paste according to claim 2.

15. A solar battery cell, comprising:
a semiconductor substrate;
a light-reception-surface-side electrode arranged on one main surface of said semiconductor substrate opposed to each other; and
a back electrode arranged on the other main surface,
said light-reception-surface-side electrode comprising a first electrode which is a fired first Ag electrode paste and a second electrode which is a fired second Ag electrode paste disposed on the first electrode, and
wherein the fired second Ag electrode paste is a fired paste according to claim 1.

16. A method of manufacturing a solar battery cell including a semiconductor substrate, a light-reception-surface-side electrode arranged on one main surface of said semiconductor substrate opposed to the one main surface, and a back electrode arranged on the another main surface and having such a structure that said light-reception-surface-side electrode comprises a first electrode which is a fired first Ag electrode paste and a second electrode which is a fired second Ag electrode paste disposed on said first electrode, comprising the steps of:
forming an Ag electrode paste pattern for said first electrode by applying the first Ag electrode paste in a prescribed pattern onto said semiconductor substrate;
forming an Ag electrode paste pattern for said second electrode by applying the Ag electrode paste according to claim 1 in a prescribed pattern onto the Ag electrode paste pattern for said first electrode; and
simultaneously firing the Ag electrode paste pattern for said first electrode and the Ag electrode paste pattern for said second electrode.

17. A method of manufacturing a solar battery cell including a semiconductor substrate, a light-reception-surface-side electrode arranged on one main surface of said semiconductor substrate opposed to the one main surface, and a back electrode arranged on the another main surface and having such a structure that said light-reception-surface-side electrode comprises a first electrode which is a fired first Ag electrode paste and a second electrode which is a fired second Ag electrode paste disposed on said first electrode, comprising the steps of:
forming an Ag electrode paste pattern for said first electrode by applying the first Ag electrode paste in a prescribed pattern onto said semiconductor substrate;
forming an Ag electrode paste pattern for said second electrode by applying the Ag electrode paste according to claim 2 in a prescribed pattern onto the Ag electrode paste pattern for said first electrode; and
simultaneously firing the Ag electrode paste pattern for said first electrode and the Ag electrode paste pattern for said second electrode.

18. A method of manufacturing a solar battery cell including a semiconductor substrate, a light-reception-surface-side electrode arranged on one main surface of said semiconductor substrate opposed to the one main surface, and a back electrode arranged on the another main surface and having such a structure that said light-reception-surface-side electrode comprises a first electrode which is a fired first Ag electrode paste and a second electrode which is a fired second Ag electrode paste disposed on said first electrode, comprising the steps of:
forming an Ag electrode paste pattern for said first electrode by applying the first Ag electrode paste in a prescribed pattern onto said semiconductor substrate;
forming an Ag electrode paste pattern for said second electrode by applying the Ag electrode paste according to claim 5 in a prescribed pattern onto the Ag electrode paste pattern for said first electrode; and
simultaneously firing the Ag electrode paste pattern for said first electrode and the Ag electrode paste pattern for said second electrode.

19. A method of manufacturing a solar battery cell including a semiconductor substrate, a light-reception-surface-side electrode arranged on one main surface of said semiconductor substrate opposed to the one main surface, and a back electrode arranged on the another main surface and having such a structure that said light-reception-surface-side electrode comprises a first electrode which is a fired first Ag electrode paste and a second electrode which is a fired second Ag electrode paste disposed on said first electrode, comprising the steps of:
forming an Ag electrode paste pattern for said first electrode by applying the first Ag electrode paste in a prescribed pattern onto said semiconductor substrate;
forming an Ag electrode paste pattern for said second electrode by applying the Ag electrode paste according to claim 7 in a prescribed pattern onto the Ag electrode paste pattern for said first electrode; and
simultaneously firing the Ag electrode paste pattern for said first electrode and the Ag electrode paste pattern for said second electrode.

20. A method of manufacturing a solar battery cell including a semiconductor substrate, a light-reception-surface-side electrode arranged on one main surface of said semiconductor substrate opposed to the one main surface, and a back electrode arranged on the another main surface and having such a structure that said light-reception-surface-side electrode comprises a first electrode which is a fired first Ag electrode paste and a second electrode which is a fired second Ag electrode paste disposed on said first electrode, comprising the steps of:
forming an Ag electrode paste pattern for said first electrode by applying the first Ag electrode paste in a prescribed pattern onto said semiconductor substrate;
forming an Ag electrode paste pattern for said second electrode by applying the Ag electrode paste according to claim 10 in a prescribed pattern onto the Ag electrode paste pattern for said first electrode; and
simultaneously firing the Ag electrode paste pattern for said first electrode and the Ag electrode paste pattern for said second electrode.
